(19) United States
(12) Patent Application Publication
(10) Pub. No.: US 2007/0141818 A1
(43) Pub. Date: Jun. 21, 2007

(54) Method of depositing materials on full face of a wafer

(76) Inventor: Bulent Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/313,249

(22) Filed: Dec. 19, 2005

(51) Int. Cl. H01L 21/20

(52) U.S. Cl. 438/584

(57) ABSTRACT

Methods of forming conductive layers over a substrate include contacting a barrier layer with an electrical contact and establishing a relative motion between the electrical contact and the barrier layer for a predetermined period of time, thereby electrodepositing conductive material from a process solution onto the barrier layer. The methods may be repeated to form an other conductive layer over the barrier layer.

### CROSS-REFERENCE TO RELATED APPLICATIONS

This application is related to the NT-001 family: U.S. Pat. Nos. 6,176,992 (issued Jan. 23, 2001), 6,402,925 (issued Jun. 11, 2002), 6,676,822 (issued Jan. 13, 2004) and 6,902,659 (issued Jun. 7, 2005); and U.S. patent application Ser. No. 10/292,750 (filed Nov. 12, 2002). This application is also related to the NT-105 family: U.S. Pat. No. 6,497,800 (issued Dec. 24, 2002); and U.S. patent application Ser. Nos. 10/302,213 (filed Nov. 22, 2002), 10/459,323 (filed Jun. 10, 2003), 10/459,320 (filed Jun. 10, 2003) and 10/459,321 (filed Jun. 10, 2003). This application is also related to the NT-109 family: U.S. Pat. No. 6,482,307 (issued Nov. 19, 2002). This application is also related to the NT-200 family: U.S. Pat. Nos. 6,610,190 (issued Aug. 26, 2003) and 6,942,780 (issued Sep. 13, 2005); and U.S. patent application Ser. No. 11/225,913 (filed Sep. 13, 2005). This application is also related to the NT-215 family: U.S. patent application Ser. Nos. 10/282,930 (filed Oct. 28, 2002), 10/282,911 (filed Oct. 28, 2002) and 10/283,025 (filed Oct. 28, 2002). This application is also related to the NT-339 family: U.S. patent application Ser. No. 11/232,718 (filed Sep. 21, 2005).

### FIELD

The present invention generally relates to semiconductor processing technologies and, more particularly, to direct electrodeposition processes.

### BACKGROUND

Conventional integrated circuits generally include a semiconductor substrate, usually a silicon wafer, active devices formed on the wafer and a plurality of sequentially-formed dielectric interlayers such as silicon dioxide and conductive paths or interconnects made of conductive materials which interconnect the devices. Interconnects are usually formed by filling a conductive material in trenches etched into the dielectric interlayers. In an integrated circuit, multiple levels of interconnect networks laterally extend with respect to the substrate surface. Interconnects formed in different layers can be electrically connected using vias or contacts. A metallization process can be used to fill such features, e.g., via openings or trenches with a conductive material, or to form, e.g., pads or contacts.

Copper and copper alloys have received considerable attention as interconnect materials because of their superior electromigration and low resistivity characteristics. The preferred method of copper metallization is electroplating. FIG. 1 shows a substrate 10 prepared for an electroplating process. The substrate 10 is an exemplary surface portion on a front surface of the wafer W shown in FIG. 2, which includes a border or peripheral region between the edge of the wafer W and the rest of the surface or the central surface region of the wafer W. Referring back to FIG. 1, for interconnect fabrication, the substrate 10 includes a dielectric layer 12 having features 14, such as vias and trenches, formed in it. The substrate 10 is typically coated with a barrier layer 16 and a seed layer 18. Typical barrier layer materials include tungsten, tantalum, titanium, their alloys, and their carbides and/or nitrides. The barrier layer 16 coats the substrate to ensure good adhesion and acts as a barrier to prevent diffusion of the copper into the dielectric layers and into the semiconductor devices. The seed layer 18, which is often a copper layer, is deposited on the barrier layer 16. The seed layer 18 forms a conductive material base for the copper film growth during subsequent copper deposition. As shown at the left side in FIG. 1, to enable copper deposition from a copper-containing electrolyte, an electrical contact is connected to the seed layer 18 and a potential difference is established between an electrode and the seed layer 18. This way, copper deposition on the seed layer 18 is initiated and the small features are filled with copper in a bottom-up fashion with the help of specialized additives (such as accelerators and suppressors) present in the electrolyte. Robustness of seed layer is important for this gap fill process. If the seed layer 18 within the narrow features is discontinuous, and/or oxidized defects such as voids form in the features, higher interconnect resistance and reliability problems arise.

Copper seed layers for copper interconnects are typically deposited by physical vapor deposition (PVD) techniques although chemical vapor deposition or atomic layer deposition methods are also being investigated. The typical seed layer thickness for 90 nanometer (nm) node interconnects has been about 100 nm. This is the thickness that gets deposited on the top surface of the structure shown in FIG. 1. The thickness of the seed layer that actually gets deposited on the vertical side walls and the bottom surface of the features 14 are much thinner, typically less than 10% of the seed layer thickness at the top, depending upon the width, the depth and the aspect ratio (depth-to-width ratio) of the feature. As the width of the feature gets smaller and its aspect ratios gets larger, the step coverage gets poorer, i.e., less of the seed layer material gets deposited on the internal surface of the feature. Although presence of a robust seed layer on the internal surface of a feature positively impacts the gap fill performance, thickness of the seed layer within the feature needs to be minimized so that more of the volume within the feature is filled with high quality electroplated copper. This is why, as the feature sizes of interconnects go to 45 nanometers and beyond, seed layer thickness deposited on the top surface of the wafers are reduced to the range of 10-40 nm. The most common problem associated with such thin seed layer deposition is poor step coverage, which may give rise to discontinuities in the seed layer and related defects, especially within the smallest features with highest aspect ratios. The seed layer thickness at the lower portions or on the side-walls of the vias and trenches may be very low, such as less than 2 nm, or the seed layer at such locations may be discontinuous. Thin portions of the seed layer may contain large amounts of oxide phases that are not stable in plating solutions. During the subsequent copper deposition process, such defective areas cause unwanted voids in the copper filling, leading into inadequately filled vias and trenches and high resistance and low lifetime in the interconnect structure. In fact, the oxidation problem is further exacerbated with the exposure of seed layers to outside conditions as the seed layer coated wafers is transported from the seed deposition unit to an electrochemical deposition unit for copper fill.

Establishing an electrical connection to such thin seed layers presents another difficulty. When such delicate layers are physically touched by electrical contacts, they may get smeared, scratched, lifted up, or otherwise damaged. Damaged areas of seed layers do not conduct electricity adequately. Therefore, any discontinuity or damaged area in the seed layer around the perimeter of the workpiece or wafer causes variations in delivered current density, which variations in turn impact the plating uniformity negatively.

As stated above, as technology nodes are going to 45 nm and below, there may be a need to totally eliminate the use of a copper seed layer and deposit copper directly on a barrier layer or a nucleation layer such as a ruthenium (Ru) layer. In this case the resistivity of the barrier layer or the nucleation layer is much larger than copper (at least 4× larger). Consequently, when an electrical contact is made to this high resistivity layer for the purpose of electrodepositing a copper layer, the contact resistance is expected to be larger than the contact resistance with a copper seed layer. When large current densities are passed through such contacts made to high resistivity thin layers, excessive heating occurs at points where the electrical contacts physically touch the thin layers. Excessive voltage drop at these locations, sparking and heating cause damage to the thin barrier layer and/or the nucleation layer, exacerbating the problem even more and causing further non-uniformities in the deposited copper layers.

To this end, there is a need for alternative methods to allow deposition of conductors, such as copper, directly on wafers comprising barrier/nucleation layers, without causing damage to such layers and without causing non-uniformities in the deposited conductor.

### SUMMARY

According to one aspect of the invention, a method of electrochemically processing a wafer, which includes a conductive film coating a front surface of the wafer and at least one cavity formed in the front surface, is disclosed. The method comprises contacting a portion of the conductive film with at least one electrical contact member. A relative motion is established between the wafer and the at least one electrical contact member while in contact with the portion of the conductive film. During said relative motion, a first conductive layer is electrodeposited onto the conductive film, including the portion of the conductive film, under a first set of electrochemical processing conditions, where the first conductive layer partially fills the at least one cavity and extends over the front surface. The electrical resistivity of the conductive film is substantially higher than the electrical resistivity of the first conductive layer. A second conductive layer is electrodeposited onto the first conductive layer under a second set of electrochemical processing conditions to completely fill the at least one cavity and to cover the entire surface of the first conductive layer.

According to another aspect of the invention, a method of electrochemically processing a wafer is disclosed. The method comprises providing a wafer having a conductive film coating a front surface of the wafer and at least one cavity formed in the front surface, and touching at least one electrical contact to a portion of the conductive film. A relative motion is established between the wafer and the at least one electrical contact touching the portion of the conductive film. During said relative motion, current of a first current density is applied to electrodeposit a first conductive layer onto the conductive film, including the portion of the conductive film, using a process solution. The first conductive layer partially fills the at least one cavity and extends over the front surface, wherein the electrical resistivity of the conductive film is substantially higher than the electrical resistivity of the first conductive layer.

According to yet another aspect of the invention, a method of electrodepositing a conductive layer on a barrier layer over a wafer is disclosed. The method includes providing a wafer having a barrier layer coating a surface of the wafer and at least one cavity formed in the surface. A process solution including a conductive material is supplied. The barrier layer is contacted with an electrical contact at a portion of the barrier layer. A relative motion is established between the electrical contact and the barrier layer for a predetermined period of time. The conductive material is electrodeposited on the barrier layer to form a conductive layer over the barrier layer including the portion that also partially fills the at least one cavity.

For purposes of summarizing the invention and the advantages achieved over the prior art, certain objects and advantages of the invention have been described above and as further described below. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figure, the invention not being limited to any particular preferred embodiment(s) disclosed.

### BRIEF DESCRIPTION OF THE DRAWINGS

FIG. 1 is a schematic cross-sectional illustration of a region of a conductive surface of a wafer and a way of conducting current to an edge region of the wafer surface;

FIG. 2 is a schematic plan view of the conductive surface of the wafer including the edge region where movable electrical contacts are placed;

FIG. 3A is a schematic cross-sectional illustration of a substrate surface including a barrier layer contacted by a contact member;

FIG. 3B is a schematic illustration of the substrate surface with barrier layer shown in FIG. 3A, wherein a conductor layer has been electrodeposited on the barrier layer;

FIG. 3C is a schematic illustration of the substrate surface with conductor layer shown in FIG. 3B, wherein another conductor layer has been electrodeposited on the conductor layer;

FIGS. 4A-4B are schematic cross-sectional illustrations of the use of stationary contacts on the conductor layer shown in FIG. 3B;

FIGS. 5A-5B are schematic plan views of positions of stationary contacts on a wafer surface and repositioning stationary contacts relative to their original position on the surface; and

FIG. 6 is a schematic plan view showing positions of movable contacts on the wafer surface.

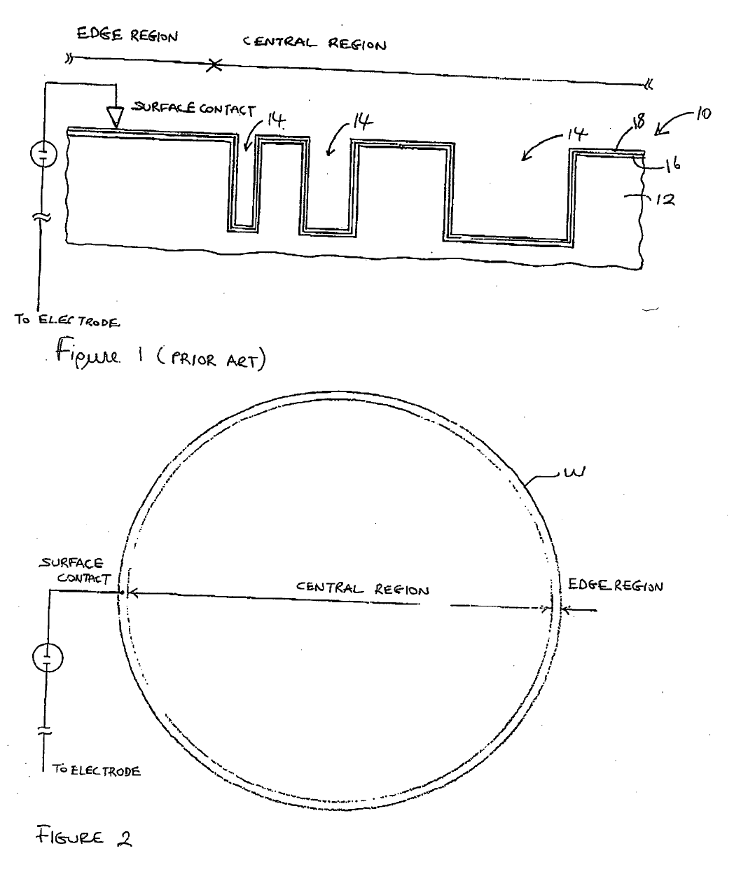

### DETAILED DESCRIPTION

From the foregoing, there are at least two problems to address to successfully process advanced node interconnects. One of the problems is that the thickness of the seed layer within the smallest features needs to be minimized. Another problem is that the thin layer should adhere well, be continuous and be free of defects. One solution to these problems is to replace the non-conformal PVD seed layer by an electrodeposited thin and conformal seed layer. Another approach is to carry out gap fill deposition directly on a barrier type material which acts as a nucleation layer without using a seed layer. These approaches will be discussed below.

A preferred embodiment of the invention provides a method of electrodepositing a first conductive layer directly on a second conductive layer, where the second conductive layer is less electrically conductive than the first conductive material. One example of this may be depositing copper directly onto a barrier layer, which is formed on a substrate, without having a highly conductive copper seed layer on the barrier layer. In the context of this application, “barrier layer” is defined as a layer or a multitude of layers interposed between a dielectric and deposited conductor such as copper to inhibit the conductor from diffusing into the dielectric. The substrate surface (or face) may include features or cavities and the barrier layer covers the entire substrate surface.

In a preferred embodiment of the invention, a first conductive layer is formed under a first set of electrochemical processing conditions and a second conductive layer is formed over the first conductive layer under a second set of processing conditions. The first set of electrochemical processing conditions includes, without limitation, using a process solution with a first composition and applying current of a first current density, and the second set of electrochemical processing conditions includes, without limitation, using a process solution with a second composition and applying current of a second current density. In some embodiments, the first composition is equivalent to the second composition. In other embodiments, the first composition is not equivalent to the second composition. In some embodiments, the first current density is equivalent to the second current density. In other embodiments, the first current density is not equivalent to the second current density. In some embodiments, the second current density is larger than the first current density.

In some embodiments, the first conductive layer and the second conductive layer are electrodeposited in the same electrodeposition station. In other embodiments, the first conductive layer and the second conductive layer are electrodeposited in different electrodeposition stations. It will be appreciated that “electrodeposition station” in the context of the present invention includes any chamber, apparatus, or reaction space used for electrodeposition.

In one embodiment of the present invention, in a first process step, a first layer is directly electrodeposited on the barrier layer using a process solution having a first chemical composition. The first layer is a continuous conductive film such as a copper film coating the internal walls of the features and extending on the surface of the substrate. In a second step of the process, a second layer is electrodeposited onto the first layer using a process solution having a second chemical composition. In the illustrated embodiment, the second chemical composition is different from the first chemical composition. The second layer fills the features completely and extends on the surface of the substrate. Furthermore, the second layer is a conductive layer such as a copper layer and may be electrodeposited at a single deposition step or multiple deposition steps, each partially filling the feature until the feature is completely filled.

In another embodiment of the present invention, a single process solution with a predetermined composition is used to form the first layer and the second layer (i.e., the first and second chemical compositions are equivalent). In this embodiment, a first electrodeposition current density is used when the first layer is deposited, and a second current density, which may be higher than the first current density, is used when the second layer is deposited. In both embodiments, during the first step, a relative motion is preferably established between the wafer and contacts, providing current to the surface and the substrate. During the second step, the relative motion between the wafer and contacts may or may not be established.

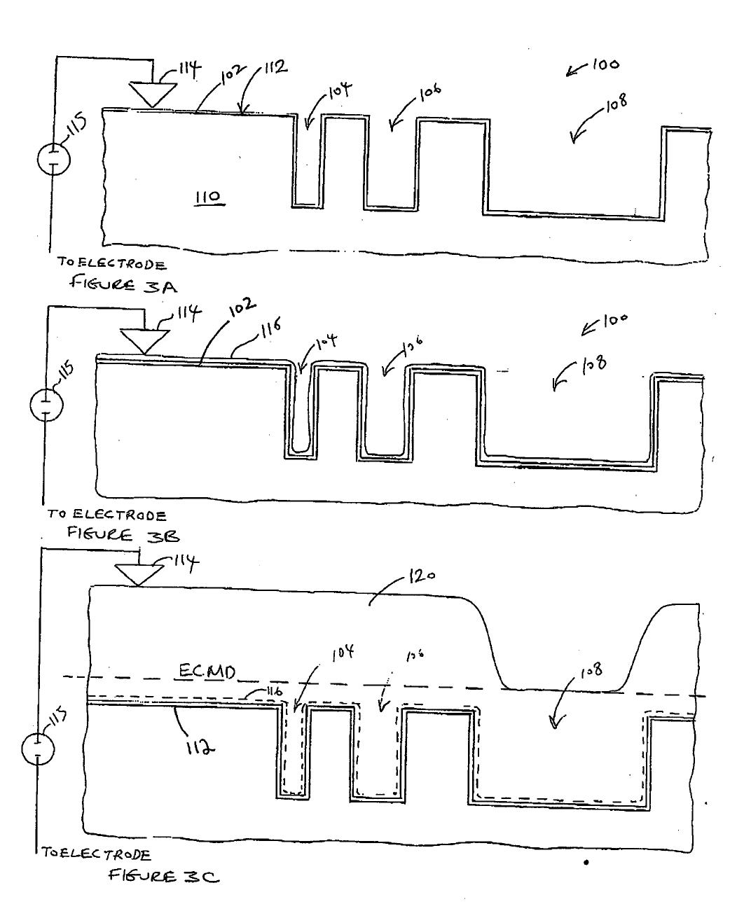

FIG. 3A shows an exemplary substrate 100 including a conductive film 102. As will be described below, a conductive material layer or a conductive layer, preferably copper, will be electrochemically formed on the conductive film 102 using processes described below. In accordance with preferred embodiments of the present invention, the electrical resistivity of the conductive film 102 is higher than the electrical resistivity of the conductive layer. An exemplary electrical resistivity for the conductive film may be between about 5×10⁻⁶ and 15×10⁻⁶ ohm cm, and for the conductive layer between about 1×10⁻⁶ and 2×10⁻⁶ ohm cm. Further, an exemplary conductive film may comprise ruthenium (Ru) and barrier layer materials, such as tantalum (Ta), tungsten (W), tantalum nitride (TaN), tungsten (carbo) nitride (WCN), titanium (Ti), titanium nitride (TiN), and possible combinations thereof. In some embodiments, the conductive film 102 may be a ruthenium (Ru) film. In other embodiments, the conductive film 102 may be a composite of various materials, such as a Ta/Ru stack or Ta/TaN/Ru stack.

For purpose of clarity, the substrate 100 exemplifies an edge portion of a wafer which may be identical to the wafer W shown in FIG. 2. The substrate 100 includes features such as a via 104, a mid-size trench 106 and a large trench 108 formed in a dielectric layer 110 using conventional techniques. In this embodiment, an upper surface 112 of the dielectric layer 110 and the features 104, 106, 108 are lined with the conductive film 102 or barrier layer in this embodiment. The barrier layer 102 preferably covers the entire surface of the wafer, including the edge or the circumference, and in certain cases may wrap around the vertical edge or bevel of the wafer. Although edge region in the figures is shown without features, this is for purpose of clarity; in reality, the features may also extend into the edge region. The term “edge region”, in this embodiment, defines an area extending from the periphery of the back surface of the wafer through the vertical edge or bevel of the wafer to the periphery of the front surface of the wafer.

As will be described more fully below, electrodeposition is preferably performed on the substrate 100 while a potential difference is applied between a contact member 114 and an electrode (not shown) and while a process solution(s) forms an electrical pathway between the wafer surface and the electrode by wetting both. The contact member 114 and the electrode are connected to terminals of a power supply 115 to apply a potential difference between them. The wafer W can be held by a wafer carrier (not shown) and may be rotated and/or translated during deposition. In one embodiment, the contact member 114 may be dynamically engaged with the barrier layer 102 and a relative motion is established between the contact member 114 and the substrate 100. With such dynamic configuration, depositing conductive layer may also grow on the edge region (including portion of the barrier layer at the edge of the wafer) where the contact member touches or contacts the substrate 100. Without such relative motion, little or no conductor tends to grow in the immediate vicinity of the contact member 114. While the illustrated embodiment shows one contact member, more than one contact member can be used to perform this process.

As shown in FIG. 3B, in a first step of an embodiment of the present invention, a first conductive layer 116 or a first copper layer (which has high electrical conductivity) is directly electrodeposited onto the barrier layer 102 (which has low electrical conductivity) from a first process solution. During the deposition, a relative motion is established between the contact member 114 and the substrate 100 for a predetermined time period (or first time period, which can be, e.g., about 10 seconds to one minute) so that the first conductive layer 116 covers the surface 112 including the peripheral regions or locations which the contact member 114 touches while it moves. It should be noted that this relative motion may be continuous or step-wise (i.e., discontinuous) (as shown in FIG. 5B), where electrodeposition may be initiated with the wafer and the contact member being stationary with respect to each other at a first position. Then, after the predetermined time period, relative motion is stopped for another time period and the contact member 114 and/or the wafer W are moved with respect to each other, thus placing the contact member 114 at another position which is different than the first position. This way copper is electrodeposited at locations that were shadowed by the contact members 114 when contact members 114 were at the first position.

The first process solution is an electrodeposition electrolyte including a chemical composition which is optimized for low current deposition. An exemplary first process solution includes high pH chemical compositions, such as a pyrophosphate copper plating composition or a composition where copper ions are complexed with a tartrate ligand, such as, e.g., sodium tartrate or diethyl tartrate. Typical pH levels of such solutions are in the range of about 7 to 13.5. The first conductive layer 116 is preferably a thin film conformally coating the barrier layer 102 and partially filling the features 104-108. During electrodeposition of the first conductive layer 116, a current density of about 0.01 to 10 milliamperes/cm² (mA/cm²), preferably about 0.1-5 mA/cm², is preferably used if direct current (DC) power is utilized. Alternatively, if a pulsed power supply is employed, current pulses of short duration (or period) and high current density, may be used. As an example, if DC power is used, a current density in the range of about 5-20 mA/cm² and a pulse duration of less than 1 second (sec), preferably less than 100 milliseconds (msec), may be applied. Depending on the feature size, the thickness of the first conductive layer 116 may vary. For example, for a feature size of 30 nanometers (nm), the thickness of the first conductive layer 116 may be less than about 5 nm.

As shown in FIG. 3C, upon deposition of the first conductive layer 116, in a second step of the embodiment, a second conductive layer 120 or a second copper layer is electrodeposited from a second process solution onto the first copper layer 116. The second conductive layer 120 fills the features 104-108 completely and extends over the upper surface 112 of the substrate 100. Preferably, during deposition a relative motion is established between the contact member 114 and the substrate 100 for a second time period (e.g., about 30 seconds to 2 minutes) so that the second conductive layer can grow over the edge region on which the contact member 114 moves. Depending on the electrodeposition technique used, the second copper layer 120 may be a non-planar layer or a planar layer. If a standard electrochemical deposition process (ECD) is used, the second conductive layer 120 is a non-planar layer. If a planar deposition technique, such as electrochemical mechanical deposition (ECMD), is used, the second layer is a planar layer (shown by a dotted line in FIG. 3C). An exemplary ECMD process is disclosed in U.S. Pat. No. 6,534,116, issued Mar. 16, 2003, the disclosure of which is incorporated herein by reference. The second process solution used to deposit the conductive layer 120 in one embodiment has a chemical composition different than the chemical composition of the first process solution. An exemplary second process (or other) solution includes the commonly used copper sulfate based copper plating solutions (both high acid and low acid) marketed by companies such as Rohm and Haas and Enthone. During electrodeposition of the second conductive layer 120, a current density of 1-50 mA/cm², preferably 5-20 mA/cm², is used. It should be noted that since the first step of the described process deposits the thin copper layer 116 everywhere on the wafer surface, including at locations where contact is made, during the second step of the embodiment electrical contact to the first layer 116 can be made very easily and high current density can be passed through such contacts without causing sparks, heating etc.

In another embodiment of the present invention, a third process solution may be used to deposit the first conductive layer 116 and the second conductive layer 120. In one embodiment, the third process solution may include the same chemical composition as the second process solution described above, and is employed for both depositions. During the process, the first conductive layer 116 is deposited using a first current density and the second conductive layer 120 is deposited using a second current density which is preferably higher than the first current density. Thus, both depositions can be performed in the same tool without replacing the electroplating bath. Exemplary current density ranges are given above.

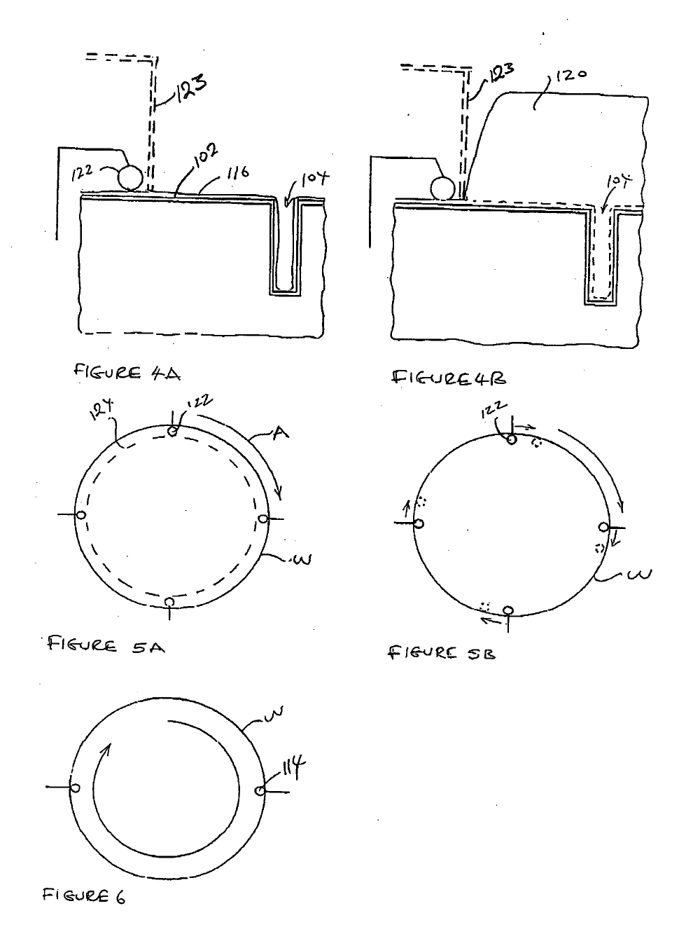

In the following description of the present invention, use of two different configurations to establish electrical contact with the wafer will be described. In the above embodiments, electrodeposition of the second conductive layer 120 may be performed using stationary contact members. FIGS. 4A-4B show in partial view a contact member 122, which is stationary relative to the wafer and placed on the first layer 116. As shown in FIG. 5A, when the wafer is rotated the contact members remain stationary on the surface, i.e., they rotate with the wafer. This is in contrast with the functionality of contact members 114 shown in FIG. 6, where a relative motion is established between the wafer and the contact members.

The stationary contact members 122 on the edge region of the wafer W may be isolated from the rest of the surface by a clamp or a contact member cover (or deposition shield) 123 (shown by dotted lines). The deposition shield 123 may be adjacent the contact member 122. As shown in FIG. 4B, as the second conductive layer 120 grows on the first conductive layer 116, a region where the contact member 122 is placed is not exposed to the deposition conditions and the second conductive layer 120 does not extend to the edge of the wafer W at this location because of this isolation by the clamp or contact member cover. It should be noted that in FIGS. 4A and 4B contact between the electrical contact member 122 and the conductive layer 116 can be easily made and high current densities may be passed through the wafer surface because the first conductive layer 116 is highly conductive and continuous over the whole front surface of the wafer W. Contact members may also be moved with respect to the wafer in a step-wise (or discontinuous) fashion during electrodeposition over the first conductive layer 116, as described above. As the deposition process continues, copper deposits onto former contact locations, which were excluded from deposition due to shielding by the contacts 122.

Although various preferred embodiments have been described in detail above, those skilled in the art will readily appreciate that many modifications of the exemplary embodiment are possible without materially departing from the novel teachings and advantages of this invention. For example, the methods described herein may be repeated as desired to form multiple (more than two) layers over the barrier layer. Therefore, it should be clearly understood that the forms of the present invention are illustrative only and are not intended to limit the scope of the present invention. All modifications and changes are intended to fall within the scope of the invention, as defined by the appended claims.

1. A method of electrochemically processing a wafer, a conductive film coating a front surface of the wafer and at least one cavity formed in the front surface, comprising:
contacting a portion of the conductive film with at least one electrical contact member;
establishing a relative motion between the wafer and the at least one electrical contact member while in contact with the portion of the conductive film;
during said relative motion, electrodepositing a first conductive layer onto the conductive film, including the portion of the conductive film, under a first set of electrochemical processing conditions, the first conductive layer partially filling the at least one cavity and extending over the front surface, wherein the electrical resistivity of the conductive film is substantially higher than the electrical resistivity of the first conductive layer; and
electrodepositing a second conductive layer onto the first conductive layer under a second set of electrochemical processing conditions to completely fill the at least one cavity and to cover the entire surface of the first conductive layer.

2. The method of claim 1, wherein the first set of electrochemical processing conditions comprises using a process solution having a first composition.

3. The method of claim 2, wherein the first set of electrochemical processing conditions comprises applying current of a first current density.

4. The method of claim 3, wherein the second set of electrochemical processing conditions comprises applying current of a second current density.

5. (canceled)

6. The method of claim 1, wherein electrodepositing the first conductive layer and electrodepositing the second conductive layer are performed in the same electrodeposition station.

7. The method of claim 1, wherein electrodepositing the first conductive layer and electrodepositing the second conductive layer are performed in different electrodeposition stations.

8-13. (canceled)

14. The method of claim 1, wherein electrodepositing the second conductive layer comprises using at least one second electrical contact member in contact with a portion of the first conductive layer.

15. (canceled)

16. The method of claim 14, wherein the at least one electrical contact member and the at least one second electrical contact member are the same contact members.

17-27. (canceled)

28. The method of claim 1, wherein the conductive film comprises material selected from the group consisting of ruthenium (Ru), tantalum (Ta), tungsten (W), titanium (Ti), titanium nitride (TiN), tantalum nitride (TaN), tungsten (carbo) nitride (WCN) and combinations thereof.

29-30. (canceled)

31. A method of electrochemically processing a wafer, comprising:
providing a wafer having a conductive film coating a front surface of the wafer and at least one cavity formed in the front surface;
touching at least one electrical contact to a portion of the conductive film;
establishing a relative motion between the wafer and the at least one electrical contact touching the portion of the conductive film; and
during said relative motion, applying current of a first current density to electrodeposit a first conductive layer onto the conductive film, including the portion of the conductive film, using a process solution, the first conductive layer partially filling the at least one cavity and extending over the front surface, wherein the electrical resistivity of the conductive film is substantially higher than the electrical resistivity of the first conductive layer.

32. The method of claim 31, further comprising applying current of a second current density to electrodeposit a second conductive layer onto the first conductive layer to completely fill the at least one cavity and to cover the surface of the first conductive layer.

33. (canceled)

34. The method of claim 32, wherein applying current of a first current density to electrodeposit a first conductive layer and applying current of a second current density to electrodeposit a second conductive layer are performed in the same electrodeposition station.

35. The method of claim 32, wherein applying current of a first current density to electrodeposit a first conductive layer and applying current of a second current density to electrodeposit a second conductive layer are performed in different electrodeposition stations.

36-52. (canceled)

53. A method of electrodepositing a conductive layer on a barrier layer over a wafer, the method comprising:
providing a wafer having a barrier layer coating a surface of the wafer and at least one cavity formed in the surface;
supplying a process solution including a conductive material;
contacting the barrier layer with an electrical contact at a portion of the barrier layer;
establishing a relative motion between the electrical contact and the barrier layer for a predetermined period of time; and
electrodepositing the conductive material on the barrier layer to form a conductive layer over the barrier layer including the portion that also partially fills the at least one cavity.

54. The method of claim 53, wherein the conductive layer covers the entire surface of the wafer including the edge of the surface.

55. The method of claim 53, further comprising electrodepositing the conductive material before establishing the relative motion but after contacting the barrier layer.

56. The method of claim 53, wherein electrodepositing occurs as the relative motion is established.

57. The method of claim 53, wherein the electrical contact makes contact with the barrier layer at the edge of the wafer.

58. The method of claim 53, further comprising supplying an other process solution including the conductive material.

59. The method of claim 58, further comprising electrodepositing the conductive material onto the conductive layer to form an other conductive layer filling the at least one cavity and extending over the conductive layer.

60. The method of claim 59, wherein the process solution has a first chemical composition and the other process solution has a second chemical composition, the first chemical composition being equivalent to the second chemical composition.

61. The method of claim 59, wherein the process solution has a first chemical composition and the other process solution has a second chemical composition, the first chemical composition not being equivalent to the second chemical composition.

62. The method of claim 53 wherein electrodepositing includes applying current of a first current density to partially fill the at least one cavity by forming the conductive layer.

63. The method of claim 62, further comprising applying current of a second current density to form an other conductive layer over the conductive layer, the other conductive layer filling the at least one cavity.

64. The method of claim 53, wherein providing a wafer having a barrier layer comprises forming the barrier layer over the wafer.
